(19) United States
(12) Patent Application Publication
(10) Pub. No.: US 2025/0379106 A1
(43) Pub. Date: Dec. 11, 2025

(54) MEASURING TILT IN SEMICONDUCTOR MANUFACTURING

(71) Applicant: Micron Technology, Inc., Boise, ID (US)

(72) Inventors: Richard T. Housley, Boise, ID (US); Nils Monserud, Half Moon Bay, CA (US); Nikhil Aditya Kumar Roy, Singapore (SG); Quinn L. Roberts, Boise, ID (US); Frank Speetjens, Boise, ID (US); Kar Wui Thong, Boise, ID (US)

(21) Appl. No.: 19/219,757

(22) Filed: May 27, 2025

Related U.S. Application Data
(60) Provisional application No. 63/656,493, filed on Jun. 5, 2024.

(51) Int. Cl. H01L 21/66; H01L 23/544; H10B 12/00; H10B 80/00

(52) U.S. Cl. CPC H01L 22/12; H01L 23/544; H10B 12/02; H10B 80/00

(57) ABSTRACT

Methods, systems, and devices for measuring tilt in semiconductor manufacturing are described. A first set of contacts and a second set of contacts may be formed on the measurement marker. Based on forming the sets of contacts, a stack of nitride and oxide materials may be deposited over the first set of contacts. Subsequently, a set of cavities may be etched through the stack of nitride and oxide materials to the set of contacts, such that a respective cavity may be etched to the set of contacts. The set of cavities may form a hollow-core light pipe that may be used for measurements over a range of optical frequencies. As such, a light may be emitted through the set of cavities, where a measurement may be obtained at the interface between the set of contacts and the set of cavities based on the emitted light.

### CROSS REFERENCE

The present application for patent claims priority to U.S. Patent Application No. 63/656,493 by Housley et al., entitled “MEASURING TILT IN SEMICONDUCTOR MANUFACTURING,” filed Jun. 5, 2024, which is assigned to the assignee hereof, and which is expressly incorporated by reference in its entirety herein.

### TECHNICAL FIELD

The following relates to one or more systems for memory, including measuring tilt in semiconductor manufacturing.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a system that supports measuring tilt in semiconductor manufacturing in accordance with examples as disclosed herein.

FIG. 2 shows an example of a memory architecture that supports measuring tilt in semiconductor manufacturing in accordance with examples as disclosed herein.

FIG. 3A shows an example of a processing step that supports measuring tilt in semiconductor manufacturing in accordance with examples as disclosed herein.

FIG. 3B shows an example of a processing step that supports measuring tilt in semiconductor manufacturing in accordance with examples as disclosed herein.

FIG. 3C shows an example of a processing step that supports measuring tilt in semiconductor manufacturing in accordance with examples as disclosed herein.

FIG. 4 shows examples of measurement markers that supports measuring tilt in semiconductor manufacturing in accordance with examples as disclosed herein.

FIG. 5A shows an example of a hollow core light pipe that supports measuring tilt in semiconductor manufacturing in accordance with examples as disclosed herein.

FIG. 5B shows an example of a semiconductor that supports measuring tilt in semiconductor manufacturing in accordance with examples as disclosed herein.

FIG. 6A shows an example of a single level measurement marker that supports measuring tilt in semiconductor manufacturing in accordance with examples as disclosed herein.

FIG. 6B shows an example of a multi-level measurement marker that supports measuring tilt in semiconductor manufacturing in accordance with examples as disclosed herein.

FIG. 7 shows an example of a graph that supports measuring misalignment in semiconductor manufacturing in accordance with examples as disclosed herein.

FIG. 8 shows a flowchart illustrating a method or methods that support measuring tilt in semiconductor manufacturing in accordance with examples as disclosed herein.

### DETAILED DESCRIPTION

Some memory systems (e.g., three dimensional (3D) not-and (NAND) systems or dynamic random access memory (DRAM)) may include a set of conductive pillars that are connected to a respective contact of a set of contacts. To manufacture such systems, the set of contacts may be formed on a semiconductor (e.g., a substrate of a wafer). Based on forming the set of contacts, a stack of nitride and oxide materials may be deposited over the set of contacts. Subsequently, a set of cavities may be etched through the stack of nitride and oxide materials to the set of contacts. In response to forming the cavities, conductive material may be deposited into each of the cavities to form the set of conductive pillars. In some examples, however, the set of conductive pillars may not be aligned with the set of contacts due to the etching process. For example, the etching process may not be completely linear (e.g., there may be bends or curves in each cavity formed by the etching process), which may lead to unintended misalignments between the set of conductive pillars and the set of contacts.

As such, to prevent the misalignment between the set of conductive pillars and the set of contacts, some manufacturing systems may measure the misalignment using a standard measurement marker, using destructive methods, or both. In one example, the standard measurement marker may be used to measure the misalignment between the cavities and the contacts, however, measuring according to such standard measurement markers may result in inaccurate measurements. In another example, an etch back process may be used to etch back the stack of nitride and oxide materials to determine the misalignment between the set of pillars and the set of contacts. While such operations may be accurate, the etch back process is destructive to the semiconductor, leading to the inability to provide the semiconductor (e.g., product) to a client. Additionally, such an etch back process may take a relatively long time (e.g., several weeks). Thus, techniques to measure the misalignment between the set of conductive pillars and the set of contacts accurately, non-destructively, and relatively quickly may be desirable. For example, once a misalignment is identified, future manufacturing processes may be modified to reduce the misalignment. If measurement techniques take a long period time, many semiconductors may be manufactured with the misalignments before a correct can be implemented.

According to the techniques, methods, and systems described herein, an imaged based measurement marker may be formed that includes the qualities of a hollow core light pipe over a range of optical frequencies, such that the misalignment created during the pattern etch process may be identified. For example, a first set of contacts and a second set of contacts may be formed on the measurement marker. Accordingly, the stack of nitride and oxide materials may be formed over the first set of contacts and a set of cavities may be etched through the stack of nitride and oxide materials to the first set of contacts, such that each cavity extends to a respective contact. Accordingly, based on the density of the cavities, the set of cavities may have the qualities of the hollow-core light pipe. Accordingly, to measure the misalignment (e.g., offset or tilt) at the interface between the set of contacts and the set of cavities, a light may be transmitted (e.g., emitted), such that the light may travel within the hollow core fiber optic created by the set of contacts and the set of cavities. For example, given that the set of cavities form a hollow-core light pipe, the emitted light may be channeled down through and back up the optic path of the cavities, thereby enabling the misalignment at the interface to be measured. Such measurement markers may be positioned across various positions of a semiconductor (e.g., wafer), such that the misalignment between set of contacts and the set of conductive pillars may be identified and accounted for during the manufacturing of the semiconductor.

In addition to applicability in memory systems as described herein, techniques for measuring tilt in semiconductor manufacturing may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by performing non-destructive measurements on semiconductors, which may result in reduce electronic waste, among other benefits.

Features of the disclosure are illustrated and described in the context of systems, devices, and circuits. Features of the disclosure are further illustrated and described in the context of processing steps, measurement markers, semiconductors, graphs, and flowcharts.

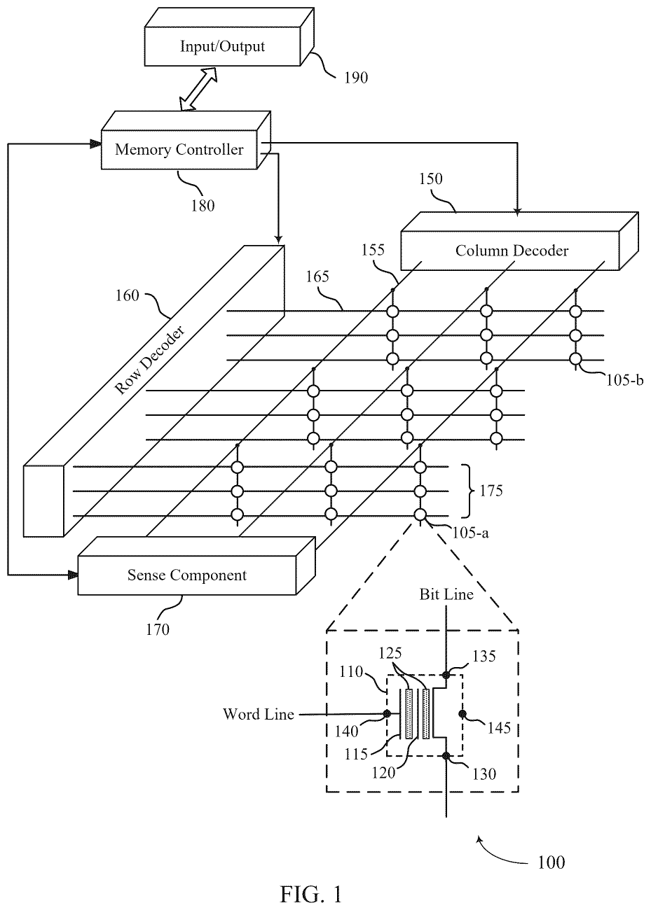

FIG. 1 shows an example of a memory device 100 that supports measuring tilt in semiconductor manufacturing in accordance with examples as disclosed herein. FIG. 1 is an illustrative representation of various components and features of the memory device 100. As such, the components and features of the memory device 100 are shown to illustrate functional interrelationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features.

The memory device 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc. Alternatively, the memory device 100 may include one or more memory cells 105, such as DRAM memory cells.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

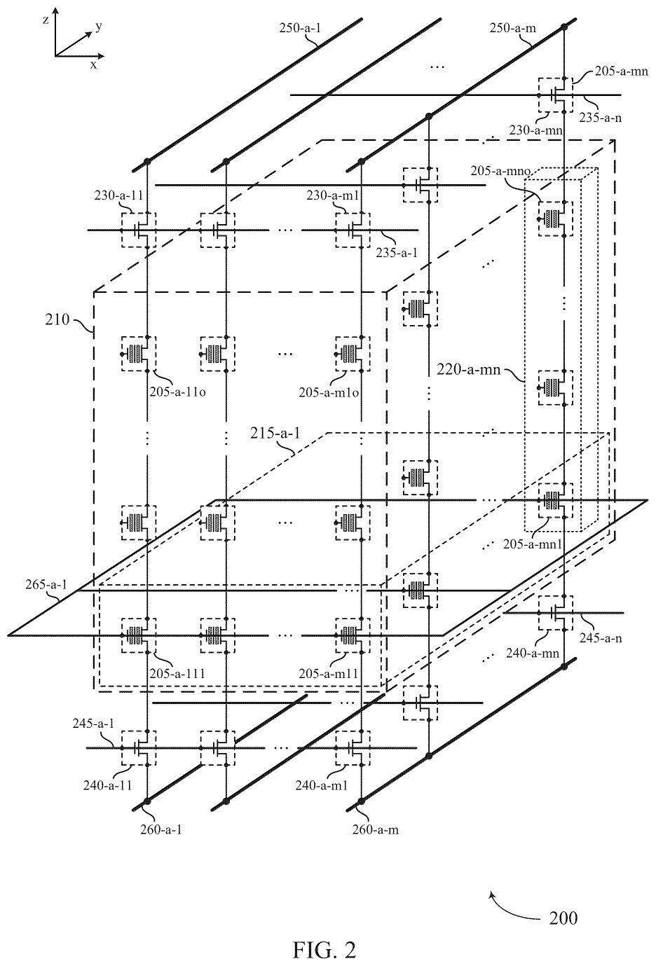

In some cases, a memory device 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory device 100 includes multiple levels (e.g., decks, materials, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105 (e.g., as described with reference to FIG. 2).

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating material.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory device 100.

Some memory systems, such as the memory device 100 or DRAM systems, may include a set of conductive pillars that are connected to a respective contact of a set of contacts. To manufacture such systems, the set of contacts may be formed on a semiconductor (e.g., a substrate of a wafer). Based on forming the set of contacts, a stack of nitride and oxide materials may be deposited over the set of contacts. Subsequently, a set of cavities may be etched through the stack of nitride and oxide materials to the set of contacts. In response to forming the cavities, conductive material may be deposited into each of the cavities to form the set of conductive pillars. In some examples, however, the set of conductive pillars may not be aligned with the set of contacts due to the etching process. For example, the etching process may not be completely linear (e.g., there may be bends or curves in each cavity formed by the etching process), which may lead to unintended misalignments between the set of conductive pillars and the set of contacts.

As such, to prevent the misalignment between the set of conductive pillars and the set of contacts, some manufacturing systems may measure the misalignment using a standard measurement marker, using destructive methods, or both. In one example, the standard measurement marker may be used to measure the misalignment between the cavities and the contacts, however, measuring according to such standard measurement markers may result in inaccurate measurements. In another example, an etch back process may be used to etch back the stack of nitride and oxide materials to determine the misalignment between the set of pillars and the set of contacts. While such operations may be accurate, the etch back process may be destructive to the semiconductor, leading to the inability to provide the semiconductor (e.g., product) to a client. Additionally, such an etch back process may take a relatively long time (e.g., several weeks). Thus, techniques to measure the misalignment between the set of conductive pillars and the set of contacts accurately, non-destructively, and relatively quickly may be desirable.

According to the techniques, methods, and systems described herein, a measurement marker may be formed that includes (e.g., encompasses) the qualities of a hollow core light pipe over a range of optical frequencies, such that the misalignment between the set of cavities and the set of contacts may be identified. For example, a first set of contacts and a second set of contacts may be formed on the measurement marker. Accordingly, the stack of nitride and oxide materials may be formed over the first set of contacts and a set of cavities may be etched through the stack of nitride and oxide materials to the first set of contacts, such that each cavity extends to a respective contact. Accordingly, based on the density of the cavities, which may be based on the density of the first set of contacts on the measurement marker, the set of cavities may have the qualities of the hollow-core light pipe. Accordingly, to measure the misalignment (e.g., offset or tilt) at the interface between the set of contacts and the set of cavities, a light may be emitted through the set of cavities. For example, given that the set of cavities form a hollow-core light pipe, the emitted light may be channeled down through and back up the optic path of the cavities, thereby enabling the misalignment at the interface to be measured. Such measurement markers may be positioned across various positions of a semiconductor (e.g., wafer), such that the misalignment between set of contacts and the set of conductive pillars may be identified and accounted for during the manufacturing of the semiconductor.

FIG. 2 shows an example of a memory architecture 200 that supports measuring tilt in semiconductor manufacturing in accordance with examples as disclosed herein. The memory architecture 200 may be an example of a portion of a memory device, such as a memory device 100. Although some elements of a set of elements (e.g., an array of elements) are included in FIG. 2, some elements may be omitted for the sake of visibility and clarity of the depicted elements. Moreover, although some elements included in FIG. 2 are labeled with reference numbers, some other corresponding elements are not labeled, though they would be understood by a person having ordinary skill in the art to be the same as or similar to the labeled elements. Aspects of the memory architecture 200 may be described with reference to an x-direction, a y-direction, and a z-direction of the illustrated coordinate system.

The memory architecture 200 includes a three-dimensional array of memory cells 205, which may be examples of memory cells 105 described with reference to FIG. 1 (e.g., transistors 110, NAND memory cells). In some examples, the memory cells 205 may be connected in a 3D NAND configuration. For example, the memory cells 205 may be included in a block 210, which may be arranged as a 3D array of m memory cells along the x-direction, n memory cells along the y-direction, and o memory cells along the z-direction. Each memory cell 205 may be located (e.g., addressed) in accordance with an index i along the x-direction, an index j along the y-direction, and an index k along the z-direction (e.g., for locating a memory cell 205-a-ijk). A memory device 100 may include any quantity of one or more blocks 210 in accordance with examples as disclosed herein, and different blocks 210 may be adjacent along the x-direction, along the y-direction, or along the z-direction, or any combination thereof.

In the example of memory architecture 200, the block 210 may be divided into a set of pages 215 (e.g., a quantity of o pages 215) along the z-direction, including a page 215-a-1 associated with memory cells 205-a-111 through 205-a-mn1. In some examples, each page 215 may be associated with the same word line 265, (e.g., a word line 165 described with reference to FIG. 1), which may be coupled with a control gate 115 of each of the memory cells 205 of the page 215. For example, page 215-a-1 may be associated with a word line 265-a-1, and other pages 215-a-i may be associated with a different respective word line 265-a-i (not shown). In some examples, a word line 265 in accordance with the memory architecture 200 may be implemented as planar conductor (e.g., in an xy-plane) that is coupled with each of the memory cells 205 of the page 215.

In the example of memory architecture 200, the block 210 also may be divided into a set of strings 220 (e.g., a quantity of (m×n) strings 220) in an xy-plane, including a string 220-a-mn associated with memory cells 205-a-mn1 through 205-a-mno. In some examples, each string 220 may include a set of memory cells 205 connected in series (e.g., along the z-direction, in which a drain of one memory cell 205 in the string 220 may be coupled with a source of another memory cell 205 in the string 220). In some examples, memory cells 205 of a string 220 may be implemented along a common channel, such as a pillar channel (e.g., a columnar channel, a pillar of doped semiconductor) along the z-direction. Each memory cell 205 in a string 220 may be associated with a different word line 265, such that a quantity of word lines 265 in the memory architecture 200 may be equal to the quantity of memory cells 205 in a string 220. Accordingly, a string 220 may include memory cells 205 from multiple pages 215, and a page 215 may include memory cells 205 from multiple strings 220.

In some examples, memory cells 205 may be programmed (e.g., set to a logic 0 value) and read from in accordance with a granularity, such as at the granularity of a page 215 or portion thereof, but may not be erasable (e.g., reset to a logic 1 value) in accordance with the granularity, such as the granularity of a page 215 or portion thereof. For example, NAND memory may instead be erasable in accordance with a different (e.g., higher) level of granularity, such as at the level of granularity the block 210. In some cases, a memory cell 205 may be erased before it may be re-programmed. Different memory devices may have different read, write, or erase characteristics.

In some examples, each string 220 of a block 210 may be coupled with a respective transistor 230 (e.g., a string select transistor, a drain select transistor) at one end of the string 220 (e.g., along the z-direction) and a respective transistor 240 (e.g., a source select transistor, a ground select transistor) at the other end of the string 220. In some examples, a drain of each transistor 230 may be coupled with a bit line 250 of a set of bit lines 250 associated with the block 210, where the bit lines 250 may be examples of bit lines 155 described with reference to FIG. 1. A gate of each transistor 230 may be coupled with a select line 235 (e.g., a string select line, a drain select line). Thus, a transistor 230 may be used to couple a string 220 with a bit line 250 based on applying a voltage to the select line 235, and thus to the gate of the transistor 230. Although illustrated as separate lines along the x-direction, in some examples, select lines 235 may be common to all the transistors 230 associated with the block 210 (e.g., a commonly biased string select node). For example, like the word lines 265 of the block 210, select lines 235 associated with the block 210 may, in some examples, be implemented as a planar conductor (e.g., in an xy-plane) that is coupled with each of the transistors 230 associated with the block 210.

In some examples, a source of each transistor 240 associated with the block 210 may be coupled with a source line 260 of a set of source lines 260 associated with the block 210. In some examples, the set of source lines 260 may be associated with a common source node (e.g., a ground node) corresponding to the block 210. A gate of each transistor 240 may be coupled with a select line 245 (e.g., a source select line, a ground select line). Thus, a transistor 240 may be used to couple a string 220 with a source line 260 based on applying a voltage to the select line 245, and thus to the gate of the transistor 240. Although illustrated as separate lines along the x-direction, in some examples, select lines 245 also may be common to all the transistors 240 associated with the block 210 (e.g., a commonly biased ground select node). For example, like the word lines 265 of the block 210, select lines 245 associated with the block 210 may, in some examples, be implemented as a planar conductor (e.g., in an xy-plane) that is coupled with each of the transistors 240 associated with the block 210.

To operate the memory architecture 200 (e.g., to perform a program operation, a read operation, or an erase operation on one or more memory cells 205 of the block 210), various voltages may be applied to one or more select lines 235 (e.g., to the gate of the transistors 230), to one or more bit lines 250 (e.g., to the drain of one or more transistors 230), to one or more word lines 265, to one or more select lines 245 (e.g., to the gate of the transistors 240), to one or more source lines 260 (e.g., to the source of the transistors 240), or to a bulk for the memory cells 205 (not shown) of the block 210. In some cases, each memory cell 205 of a block 210 may have a common bulk, the voltage of which may be controlled independently of bulks for other blocks 210.

In some cases, as part of a read operation for a memory cell 205, a positive voltage may be applied to the corresponding bit line 250 while the corresponding source line 260 may be grounded or otherwise biased at a voltage lower than the voltage applied to the bit line 250. In some examples, voltages may be concurrently applied to the select line 235 and the select line 245 that are above the threshold voltages of the transistor 230 and the transistor 240, respectively, for the memory cell 205, thereby activating the transistor 230 and transistor 240 such that a channel associated with the string 220 that includes the memory cell 205 (e.g., a pillar channel) may be electrically connected with (e.g., electrically connected between) the corresponding bit line 250 and source line 260. A channel may be an electrical path through the memory cells 205 in the string 220 (e.g., through the sources and drains of the transistors in the memory cells 205 of the string 220) that may conduct current under some operating conditions.

In some examples, multiple word lines 265 (e.g., in some cases all word lines 265) of the block 210—except a word line 265 associated with a page 215 of the memory cell 205 to be read—may concurrently be set to a voltage (e.g., VREAD) that is higher than the threshold voltage (VT) of the memory cells 205. VREAD may cause all memory cells 205 in the unselected pages 215 be activated so that each unselected memory cell 205 in the string 220 may maintain high conductivity within the channel. In some examples, the word line 265 associated with the memory cell 205 to be read may be set to a voltage, VTarget. Where the memory cells 205 are operated as SLC memory cells, VTarget may be a voltage that is between (i) VT of a memory cell 205 in an erased state and (ii) VT of a memory cell 205 in a programmed state.

When the memory cell 205 to be read exhibits an erased VT (e.g., VTarget>VT of the memory cell 205), the memory cell 205 may turn “ON” in response to the application of VTarget to the word line 265 of the selected page 215, which may allow a current to flow in the channel of the string 220, and thus from the bit line 250 to the source line 260. When the memory cell 205 to be read exhibits a programmed VT (e.g., VTarget<VT of the selected memory cell), the memory cell 205 may remain “OFF” despite the application of VTarget to the word line 265 of the selected page 215, and thus may prevent a current from flowing in the channel of the string 220, and thus from the bit line 250 to the source line 260.

A signal on the bit line 250 for the memory cell 205 (e.g., an amount of current below or above a threshold) may be sensed (e.g., by a sense component 170 as described with reference to FIG. 1), and may indicate whether the memory cell 205 became conductive or remained non-conductive in response to the application of VTarget to the word line 265 of the selected page 215. The sensed signal thus may be indicative of whether the memory cell 205 was in an erased state (e.g., storing a logic 1) or a programmed state (e.g., storing a logic 0). Though aspects of the example read operation above have been explained in the context of an SLC memory cell 205 for clarity, such techniques may be extended or altered and applied in the context of a multiple-level memory cell 205 (e.g., through the use of multiple values of VTarget corresponding to the different amounts of charge that may be stored in one multiple-level memory cell 205).

In some cases, as part of a program operation for a memory cell 205, charge may be added to a portion of the memory cell 205 such that current flow through the memory cell 205, and thus the corresponding string 220, may be inhibited when the memory cell 205 is later read. For example, charge may be injected into a charge trapping structure 120 as shown in memory cell 105-a of FIG. 1. In some cases, respective voltages may be applied to the word line 265 of the page 215 and the bulk of the memory cell 205 to be programmed such that a control gate 115 of the memory cell 205 is at a higher voltage than the bulk of the memory cell 205 (e.g., a positive voltage may be applied to the word line). Concurrently, voltages may be applied to the select line 235 and the select line 245 that are above the threshold voltages of the transistor 230 and the transistor 240, respectively, thereby activating the transistor 230 and the transistor 240, and the bit line 250 for the memory cell 205 to be programmed may be set to a relatively high voltage. This may cause an electric field such that electrons are pulled from the source of the memory cell 205 towards the drain. The electric field may also cause some of these electrons to be pulled through dielectric material 125 and thereby injected into the charge trapping structure 120 of the memory cell 205, through a process which may in some cases be referred to as tunnel injection.

In some cases, a single program operation may program some or all memory cells 205 in a page 215, as the memory cells 205 of the page 215 may all share a common word line 265 and a common bulk. For a memory cell 205 of the page 215 for which it is not desired to write a logic 0 (e.g., not desired to program the memory cell 205), the corresponding bit line 250 may be set to a relatively low voltage (e.g., ground), which may inhibit the injection of electrons into a charge trapping structure 120. Though aspects of the example program operation above have been explained in the context of an SLC memory cell 205 for clarity, such techniques may be extended and applied to the context of a multiple-level memory cell 205 (e.g., through the use of multiple programming voltages applied to the word line 265, or multiple passes or pulses of a programming voltage applied to the word line 265, corresponding to the different amounts of charge that may be stored in one multiple-level memory cell 205).

In some cases, as part of an erase operation for a memory cell 205, charge may be removed from a portion of the memory cell 205 such that current flow through the memory cell 205, and thus the corresponding string 220, may be uninhibited (e.g., allowed, at least to a greater extent) when the memory cell 205 is later read. For example, charge may be removed from a charge trapping structure 120 as shown in memory cell 105-a of FIG. 1. In some cases, respective voltages may be applied to the word line 265 of the page 215 and the bulk of the memory cell 205 to be erased such that a control gate 115 of the memory cell 205 is at a lower voltage than the bulk of the memory cell 205 (e.g., a positive voltage may be applied to the bulk), which may cause an electric field that pulls electrons out of the charge trapping structure 120 and into the bulk of the memory cell 205. In some cases, a single program operation may erase all memory cells 205 in a block 210, as the memory cells 205 of the block 210 may all share a common bulk.

Some memory systems, such as the memory architecture 200 or DRAM systems, may include a set of conductive pillars that are connected to a respective contact of a set of contacts. To manufacture such systems, the set of contacts may be formed on a semiconductor (e.g., a substrate of a wafer). Based on forming the set of contacts, a stack of nitride and oxide materials may be deposited over the set of contacts. Subsequently, a set of cavities may be etched through the stack of nitride and oxide materials to the set of contacts. In response to forming the cavities, conductive material may be deposited into each of the cavities to form the set of conductive pillars. In some examples, however, the set of conductive pillars may not be aligned with the set of contacts due to the etching process. For example, the etching process may not be completely linear (e.g., there may be bends or curves in each cavity formed by the etching process), which may lead to unintended misalignments between the set of conductive pillars and the set of contacts.

As such, to prevent the misalignment between the set of conductive pillars and the set of contacts, some manufacturing systems may measure the misalignment using a standard measurement marker, using destructive methods, or both. In one example, the standard measurement marker may be used to measure the misalignment between the cavities and the contacts, however, measuring according to such standard measurement markers may result in inaccurate measurements. In another example, an etch back process may be used to etch back the stack of nitride and oxide materials to determine the misalignment between the set of pillars and the set of contacts. While such operations may be accurate, the etch back process may be destructive to the semiconductor, leading to the inability to provide the semiconductor (e.g., product) to a client. Additionally, such an etch back process may take a relatively long time (e.g., several weeks). Thus, techniques to measure the misalignment between the set of conductive pillars and the set of contacts accurately, non-destructively, and relatively quickly may be desirable.

According to the techniques, methods, and systems described herein, a measurement marker may be formed that includes (e.g., encompasses) the qualities of a hollow core light pipe over a range of optical frequencies, such that the misalignment between the set of cavities and the set of contacts may be identified. For example, a first set of contacts and a second set of contacts may be formed on the measurement marker. Accordingly, the stack of nitride and oxide materials may be formed over the first set of contacts and a set of cavities may be etched through the stack of nitride and oxide materials to the first set of contacts, such that each cavity extends to a respective contact. Accordingly, based on the density of the cavities, which may be based on the density of the first set of contacts on the measurement marker, the set of cavities may have the qualities of the hollow-core light pipe. Accordingly, to measure the misalignment (e.g., offset or tilt) at the interface between the set of contacts and the set of cavities, a light may be emitted through the set of cavities. For example, given that the set of cavities form a hollow-core light pipe, the emitted light may be channeled down through and back up the optic path of the cavities, thereby enabling the misalignment at the interface to be measured. Such measurement markers may be positioned across various positions of a semiconductor (e.g., wafer), such that the misalignment between set of contacts and the set of conductive pillars may be identified and accounted for during the manufacturing of the semiconductor.

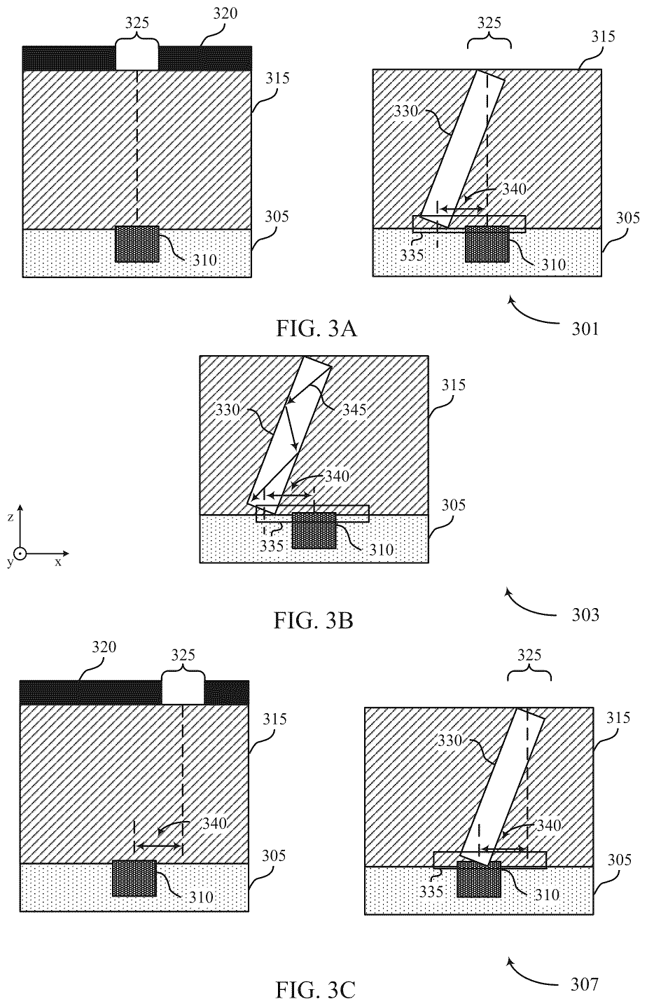

FIG. 3A shows an example of a processing step 301 that supports measuring tilt in semiconductor manufacturing in accordance with examples as disclosed herein. For example, aspects of the processing step 301 may be utilized to manufacture the memory device 100 and the memory architecture 200 as described herein with reference to FIGS. 1 and 2. Additionally, aspects of the processing step 301 may be utilized to manufacture one or more DRAM systems. As described herein, some systems (e.g., 3D NAND or DRAM) may be scaling vertically, which may lead to several high aspect ratio (HAR) etches and tight overlay specifications. Accordingly, to support such vertical scaling, the systems may include a set of conductive pillars that are configured to couple with a respective contact 310. However, such HAR structures may introduce additional tilts and/or bends in etching processes, which may lead to misalignments. The techniques described in the context of the processing step 301 may illustrate the manufacturing of such structures and various techniques to measure such misalignments.

For example, a semiconductor 305 (e.g., substrate of a wafer) may be formed. In response to forming the semiconductor 305, a contact 310 of a set of contacts 310 (not shown) may be formed on the semiconductor 305. Based on forming the contact 310, a stack of nitride and oxide materials 315 may be formed (e.g., deposited) over the contact 310. Based on forming the stack of nitride and oxide materials 315, a resistive material 320 (e.g., photo resist material) may be deposited over the stack of nitride and oxide materials. In such examples, a gap 325 of a set of gaps 325 (not shown) in the resistive material may be etched or formed during the deposit of the resistive material 320, where a center of the gap 325 may align with a center of the contact 310. That is, a respective gap 325 may be formed in the resistive material 320 over the stack of nitride and oxide materials 315, where a center of the respective gaps 325 may align with a center of a respective contact 310 of the set of contacts 310.

Accordingly, in response to depositing the resistive material 320, a cavity 330 of a set of cavities 330 (not shown) may be formed (e.g., etched) through the gap 325, through the stack of nitride and oxide materials 315, and to the contact 310. In such examples, a dry etching procedure may be performed to etch the cavity 330. As shown, in response to etching the cavity 330, the resistive material 320 may be removed. In some cases, however, because the etching procedure may not be linear (e.g., there may be bends or curves in each cavity 330 formed by the etching process, especially as the height of the device increases), the cavity 330 may not align with the contact 310. For example, due to the nonlinear nature of the etching process, a misalignment 340 (e.g., offset or tilt) may occur at an interface 335 (e.g., region of interest) between the cavity 330 and the contact 310. As described herein, the misalignment 340 may be quantized as a vector including a first magnitude in the x-direction and a second magnitude in the y-direction.

Some systems may utilize various measurement techniques to measure the misalignment 340. In one example, a standard measurement marker may be used to measure the misalignment 340, however, measuring according to such standard measurement markers may result in inaccurate measurements. For example, incident light from optical overlay metrology tools may be scattered within a top section of the stack of nitride and oxide materials 315 formed on the standard measurement marker, leading to inaccurate measurements of the misalignment 340. In another example, a destructive process, such as an etch back process, may be used to thin the stack of nitride and oxide materials 315 and isolate (e.g., show) the misalignment 340. While such operations may be accurate, the etch back process is destructive to the semiconductor 305, leading to the inability to provide the semiconductor 305 (e.g., product) to a client. Additionally, such an etch back process may take a relatively long time (e.g., a week to several weeks). In some examples, once a misalignment is identified, future manufacturing processes may be modified to reduce the misalignment. If measurement techniques take a long period time, many semiconductors may be manufactured with the misalignments before a correct can be implemented. Thus, techniques to measure the misalignment between the set of conductive pillars and the set of contacts accurately, non-destructively, and relatively quickly may be desirable.

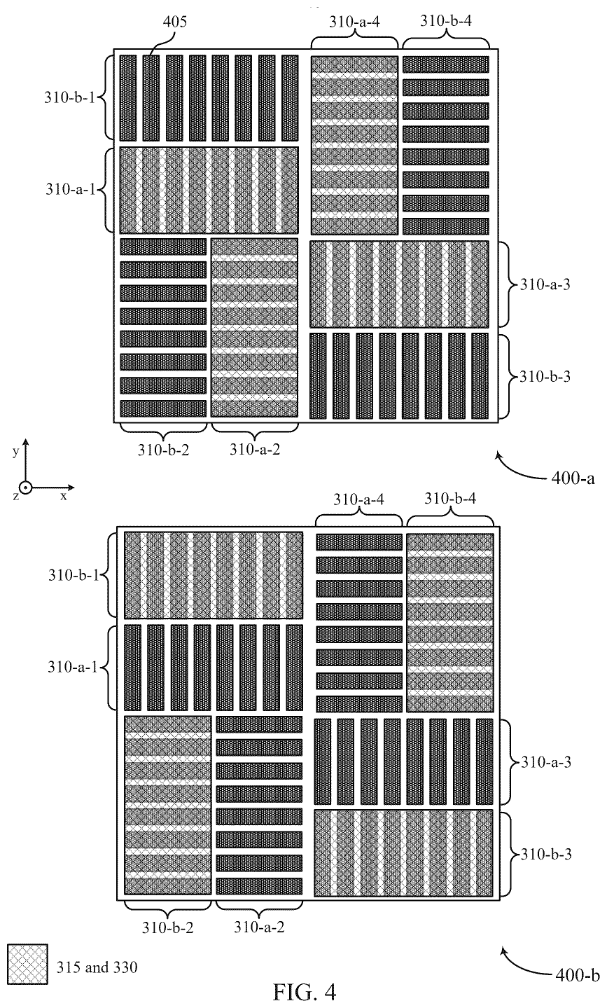

FIG. 3B shows an example of a processing step 303 that supports measuring tilt in semiconductor manufacturing in accordance with examples as disclosed herein. Aspects of the processing step 303 may be utilized by manufacturing systems to measure the misalignment 340 at the interface 335 between the cavity 330 and the contact 310. For example, a measurement marker may be formed on the semiconductor 305, where the measurement marker may include multiple contacts 310, the stack of nitride and oxide materials 315 formed over the multiple contacts 310, and multiple cavities 330 etched through the stack of nitride and oxide materials 315 to the multiple contacts 310 according to a hollow core light pipe (e.g., formed in a HCP layout), such that a respective cavity 330 extends to a respective contact 310. In such examples, due to a density of the contacts 310, which may affect a density of the cavities 330, the measurement marker may have the characteristics of a hollow-core light pipe over a range of optical frequencies. Due to such characteristics, a light 345 may be emitted from metrology tools through each of the cavities 330 (e.g., through the pillar pattern) without suffering light scattering effects (as seen in standard measurement markers). For example, using such designs, the light may be reflected (e.g., bounced) off of the outer wall of the hollow core light pipe created by the cavities 330, where such cavities 330 may have a different refractive index (N) and extinction coefficient (K) than those of the air within the hollow core fiber optic created by the cavities 330. A wavelength of the light 345 is selected to be within the range of optical frequencies supported by the hollow-core light pipe. Accordingly, the misalignment 340 may be measured based in part on emitting the light 345 through each of the cavities 330, the light traveling down the light pipe (using principles of internal reflection), and returning to a sensor. Techniques to manufacture the measurement marker and perform such measurements may be further described herein with reference to FIG. 4.

FIG. 3C shows an example of a processing step 307 that supports measuring tilt in semiconductor manufacturing in accordance with examples as disclosed herein. Aspects of the processing step 307 may occur after the measurement of the misalignment 340 is obtained. For example, the techniques described in the context of the processing step 307 may enable the manufacturing system to account for the misalignment 340 measured in the processing step 303, such that the cavity 330 may align with the contact 310, thereby enabling a conductive pillar, which is to be formed in the cavity 330, to be coupled with the contact 310. For example, in response to obtaining the measurement of the misalignment 340 at the interface 335, the gap 325 in the resistive material 320 may be adjusted (e.g., moved) according to the magnitude (e.g., length) and direction(s) of the misalignment 340. In this way, during the etching procedure, the cavity 330 may be etched such that the cavity 330 extends through the stack of nitride and oxide materials 315 and onto the contact 310. That is, by adjusting the gap 325 in the resistive material 320, the cavity 330 may be aligned with the contact 310 at the interface 335. The measurement of the misalignment 340 may take into account the bends and/or twists in the cavity the results from etching a high stack of materials.

FIG. 4 shows examples of measurement markers 400 that support measuring tilt in semiconductor manufacturing in accordance with examples as disclosed herein. The measurement markers 400 may be utilized by a manufacturing system to measure one or more misalignments 340 at an interface between sets of contacts 310 and sets of cavities 330 during the manufacturing of the memory device 100 and the memory architecture 200 as described herein with reference to FIGS. 1-3C.

For example, the measurement markers 400 may be formed on a first level of a semiconductor (e.g., substrate of a wafer). Based on forming the measurement marker 400 on the semiconductor, sets of contacts 310 may be formed on the measurement marker 400. That is, the measurement markers 400 may include a set of contacts 310-a and a set of contacts 310-b, where the set of contacts 310-b may be formed on an outer area of the measurement markers 400, while the set of contacts 310-a may be formed on an inner area of the measurement markers 400. The sets of contacts 310 may include one or more bars of contacts 405, where each bar of contacts 405 may include multiple individual contacts 310.

In some examples, the sets of contacts 310 may include one or more subsets of contacts formed in different directions. For example, the set of contacts 310-a may include a subset of contacts 310-a-1 and a subset of contacts 310-a-3, where the bars of contacts 405 of the subset of contacts 310-a-1 and the subset of contacts 310-a-3 may be formed in the x-direction (e.g., first direction). Additionally, the set of contacts 310-a may include a subset of contacts 310-a-2 and a subset of contacts 310-a-4, where the bars of contacts 405 of the subset of contacts 310-a-2 and the subset of contacts 310-a-4 may be formed in the y-direction (e.g., second direction). Likewise, the set of contacts 310-b may include a subset of contacts 310-b-1 and a subset of contacts 310-b-3 formed in x-direction and include a subset of contacts 310-b-2 and a subset of contacts 310-b-4 formed in the y-direction.

In such examples, the set of contacts 310-a and the set of contacts 310-b may be formed (e.g., printed) at a same time on the measurement markers 400. That is, the set of contacts 310-a and the set of contacts 310-b are formed at the same time. If such contacts are formed at different times, different levels, or both, the overlay measurement may be confounded (e.g., be inaccurate). For example, due to the simultaneous formation of the sets of contacts 310, the overlay (e.g., measurable offset) between the set of contacts 310-a and the set of contacts 310-b may be zero (e.g., no measurable offset). Such overlay may be zero if the overlay is measured prior to placement of a top set of contacts (e.g., ‘sea of contacts’ not shown), where the top set of contacts may be a dense unbroken patterning of contacts that create a pillar pattern. Based on such contacts (e.g., ‘sea of contacts’) being formed over the set of contacts 310 (e.g., AiM bars), the zero overlay may be detected when the measurement marker 400 is confounded.

In response to forming the sets of contacts 310, the stack of nitride and oxide materials 315 may be deposited over one of the sets of contacts 310. In the example of the measurement marker 400-a, the stack of nitride and oxide materials 315 may be deposited over the set of contacts 310-a (e.g., the inner contacts). Alternatively, in the example of the measurement marker 400-b, the stack of nitride and oxide materials 315 may be deposited over the set of contacts 310-b (e.g., the outer contacts).

Based on depositing the stack of nitride and oxide material over one of the sets of contacts 310, the set of cavities 330 may be etched through the stack of nitride and oxide materials to the sets of contacts 310. As an illustrative example, a respective stack of nitride and oxide materials 315 may be deposited over the subset of contacts 310-a-1, the subset of contacts 310-a-2, the subset of contacts 310-a-3, and the subset of contacts 310-a-3. Accordingly, respective sets of cavities 330 may be etched through the respective stacks of nitride and oxide materials 315.

As described herein, the set of cavities 330 may form a hollow-core light pipe (e.g., a fiber optic bundle or a photonic crystal fiber) over the set of contacts 310. A hollow core fiber may be an optical fiber which guides light within a hollow region, so that a relatively minor portion of the optical power propagates in the solid fiber material. The hollow-core light pipe formed by the set of cavities 330 may have similar properties as that of a photonic crystal fiber, which may use periodic distribution of refractive indexes to create a photonic bandgap effect. Such a photonic bandgap effect may enable the light 345 emitted through the set of cavities 330 to propagate to the set of contacts 310, thereby enabling the measurement of the misalignment 340 at the interface 335 between the set of contacts 310 and the set of cavities 330.

In some examples, to form the hollow-core light pipe using the set of cavities 330, a density of the individual contacts 310 of the sets of contacts 310 may be selected. The selected density of the individual contacts 310 of the sets of contacts 310 may affect the density of the set of cavities 330, due to the one-to-one cavity to contact formation. Accordingly, by selecting the density of the set of contacts 310, the characteristics of the hollow-core light pipe may be formed by etching the set of cavities 330. In such examples, the density of the individual contacts 310 of the set of contacts 310 may be based on a density of the contacts 310 formed on the semiconductor. That is, the density of the individual contacts 310 of the set of contacts 310 may be determined by the die (e.g., memory device part type) that is to be formed on the wafer. Accordingly, the density of the individual contacts 310 may match the density of the contacts 310 being formed on the wafer, such that the metrology measurement (e.g., measured misalignment) may have a relationship back to the etched pattern on the die, thereby enabling the measured misalignment, and associated correction valid for the dic.

In the example of the measurement marker 400-a, to measure the misalignment 340, a light may be emitted through the set of cavities 330 over the set of contacts 310-a. By doing so, the hollow core light pipe created by the set of cavities 330 may change the visibility of the set of contacts 310-a of the inner area of the measurement marker 400-a, resulting in measurable misalignment 340 at the interface between the set of cavities 330 and the set of contacts 310-a when compared with the set of contacts 310-b (e.g., reference contacts). In such examples, to measure the x-direction misalignment 340, a measurement tool may utilize the subset of contacts 310-a-2 and the subset of contacts 310-a-4 as the hollow core light pipe and utilize the subset of contacts 310-b-2 and the subset of contacts 310-b-4 as the reference contacts. To measure the y-direction misalignment 340, the measurement tool may utilize the subset of contacts 310-a-1 and the subset of contacts 310-a-3 as the hollow core light pipe and utilize the subset of contacts 310-b-1 and the subset of contacts 310-b-3 as the reference contacts.

In the example of the measurement marker 400-b, to measure the misalignment 340, a light may be emitted through the set of cavities 330 over the set of contacts 310-b. By doing so, the hollow core light pipe created by the set of cavities 330 may change the visibility of the set of contacts 310-b of the outer area of the measurement marker 400-b, resulting in measurable misalignment 340 at the interface between the set of cavities 330 and the set of contacts 310-b when compared with the set of contacts 310-a (e.g., reference contacts). In such examples, to measure the x-direction misalignment 340, a measurement tool may utilize the subset of contacts 310-b-2 and the subset of contacts 310-b-4 as the hollow core light pipe and utilize the subset of contacts 310-a-2 and the subset of contacts 310-a-4 as the reference contacts. To measure the y-direction misalignment 340, the measurement tool may utilize the subset of contacts 310-b-1 and the subset of contacts 310-b-3 as the hollow core light pipe and utilize the subset of contacts 310-a-1 and the subset of contacts 310-a-3 as the reference contacts.

To ensure an accuracy of the measurement of the misalignment 340, a wavelength of the light emitted through the set of cavities 330 may be selected. For example, hollow core fibers may utilize incoherent light, where various measurement tools may utilize semi-coherent light sources. Accordingly, a wavelength of the light (e.g., a white light, orange light, yellow light, among other examples) may change the response of the hollow core light pipe created by the set of cavities 330. In such examples, selecting the wavelength of the light that minimizes signal loss may be based on the density of the set of contacts 310, a pitch of the set of cavities 330, a diameter of the set of cavities 330, an ellipticity of the set of cavities 330, an air filling fraction of the set of cavities, a uniformity of the set of cavities 330, a height of the set of cavities 330, a size of the set of contacts 310, or a combination thereof.

By using the measurement markers 400, the measurement of the misalignment 340 may be obtained without destroying the semiconductor, which may increase the yield of the semiconductor and reduce electronic waste. Additionally, the use of the measurement markers 400 may not incur additional invasive procedures or practices, such as avoiding additional etches, using additional tools, creating additional manufacturing process flows, among other examples. In some examples, by using the measurement markers 400, the misalignment 340 may be measured relatively quickly and accurately and reduce production costs.

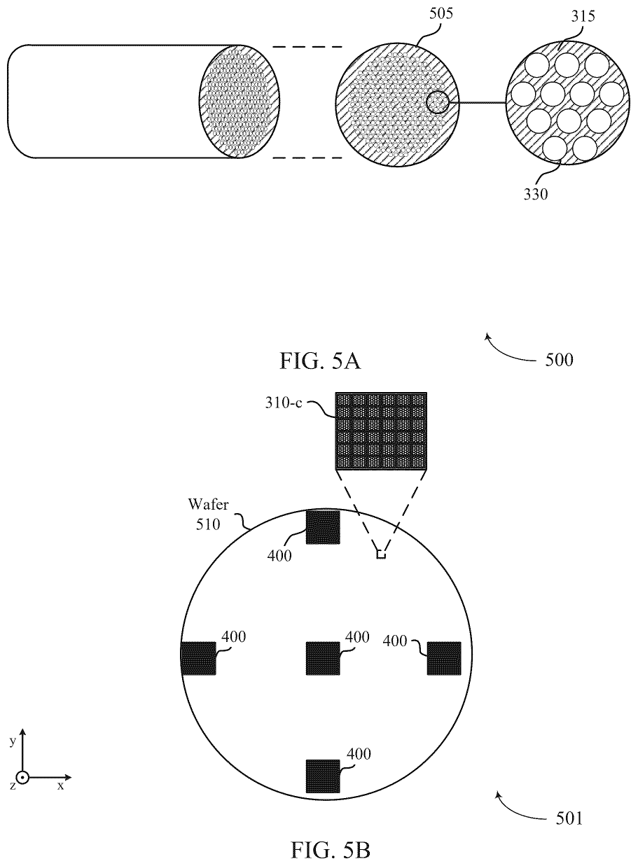

FIG. 5A shows an example of a hollow core light pipe 500 that supports measuring tilt in semiconductor manufacturing in accordance with examples as disclosed herein. Aspects of the hollow core light pipe 500 may be implemented by a manufacturing system to manufacture aspects of the memory device 100 and the memory architecture 200 as described herein with reference to FIGS. 1 and 2. Additionally, aspects of the hollow core light pipe 500 may implemented by the measurement markers 400, as described herein with reference to FIGS. 4A and 4B.

For example, the measurement markers 400 (e.g., the set of cavities 330 over the set of contacts 310) may form the hollow core light pipe 500. In such examples, the hollow core light pipe 500 may include an HCP pattern 505. For example, each of the cavities 330 of the hollow core light pipe 500 may be formed in the HCP pattern 505, where the set of cavities 330 (e.g., a series of periodic tubes) may create a photonic bandgap through the arrangement of air holes in the stack of nitride and oxide materials 315. In such examples, the set of cavities 330 may be referred to as photonic bandgap fibers. Such a photonic bandgap effect may act as a loss-free mirror confining the light 345 into the core of the hollow core light pipe 500, such that the light 345 emitted through the set of cavities 330 may propagate to the set of contacts 310, thereby enabling the measurement of the misalignment 340 at the interface 335 between the set of contacts 310 and the set of cavities 330.

FIG. 5B shows an example of a semiconductor 501 that supports measuring tilt in semiconductor manufacturing in accordance with examples as disclosed herein. Aspects of the semiconductor 501 may be implemented by a manufacturing system to manufacture aspects of the memory device 100 and the memory architecture 200 as described herein with reference to FIGS. 1 and 2. Additionally, aspects of the semiconductor 501 may implement aspects of the processing step 301, the processing step 303, the processing step 307, and the measurement marker 400 as described herein with reference to FIGS. 3A-5B.

A wafer 510 may be formed to include a substrate, where multiple contacts 310-c may be formed on the substrate of the wafer 510. In some examples, misalignments 340 between the contacts 310-c and one or more conductive pillars may be formed during subsequent steps of the manufacturing process, such as described herein with reference to FIGS. 3A and 3B. Accordingly, to measure such misalignments 340, measurement markers 400 may be formed, such that the misalignment 340 may be measured using the measurement markers 400, as described herein with reference to FIG. 4.

In such examples, the misalignment 340 at the interface between the contacts 310-c and the conductive pillars may be different based on the position of the contacts 310-c on the wafer 510. For example, a misalignment 340 at the interface between a first contact 310-c and a first conductive pillar at a first radial position of the wafer 510 (e.g., radial position of 0 nm or position close to the center of the wafer 510) may be different from a second misalignment 340 at the interface between a second contact 310-c and a second conductive pillar at a second radial position of the wafer 510 (e.g., a radial position of X nm or position closer to the edge of the wafer 510). Accordingly, to measure the respective misalignments 340 at the various positions of the wafer 510, one or more measurement markers 400 may be formed at the various positions of the wafer 510. The positions of the measurement markers 400 on substrate of the wafer 510 may be selected in order to optimize the measurements of the misalignments 340 and to reduce the quantity of measurement markers 400 formed on the wafer 510. In this way, such misalignments 340 may be measured and mitigated during subsequent manufacturing steps.

In some examples, the measurement markers 400 may be formed at a same time as the contacts 310-c. For example, the set of contacts 310 of the measurement markers 400 may be formed to mimic the pattern of contacts 310-c formed on substrate of the wafer 510, where such contacts 310-c may be used for the creation of the memory cells. In such examples, in response to forming the contacts 310-c on the wafer 510 and forming the sets of contacts on the measurement markers 400, a stack of nitride and oxide materials 315 (not shown) may be deposited over the contacts 310-c of the wafer 510 and over the measurement markers 400 (according to the techniques described herein with reference to FIG. 4). In response to depositing the stack of nitride and oxide materials 315, a set of cavities 330 (not shown) may be etched through the stack of nitride and oxide materials 315 to the contacts 310-c on the wafer 510. Similarly, a set of cavities 330 may be etched through the stack of nitride and oxide materials deposited over the measurement markers in accordance with the techniques described herein with reference to FIG. 4. In this way, the wafer 510 and the measurement markers 400 may be formed at a same time.

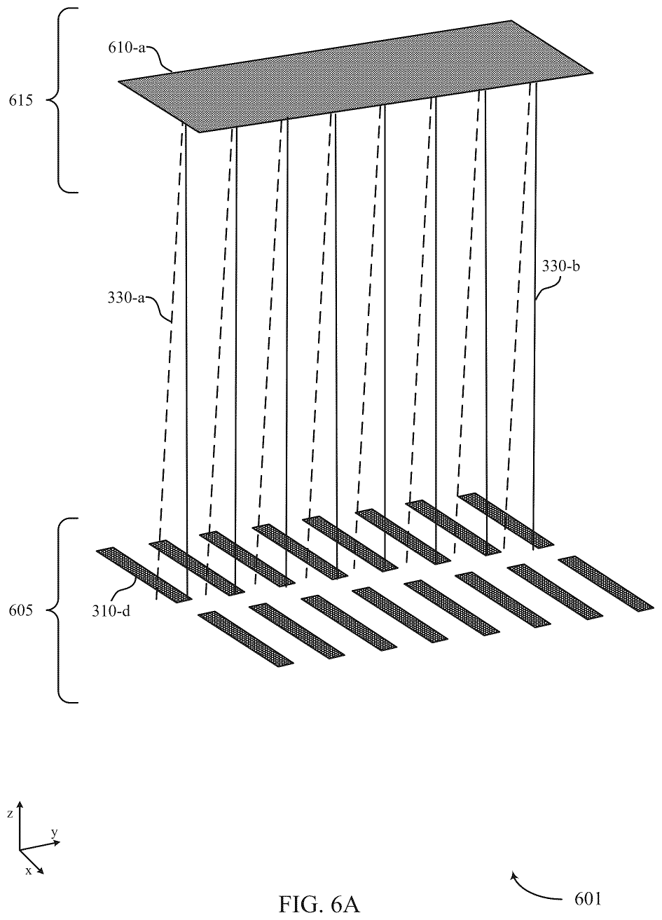

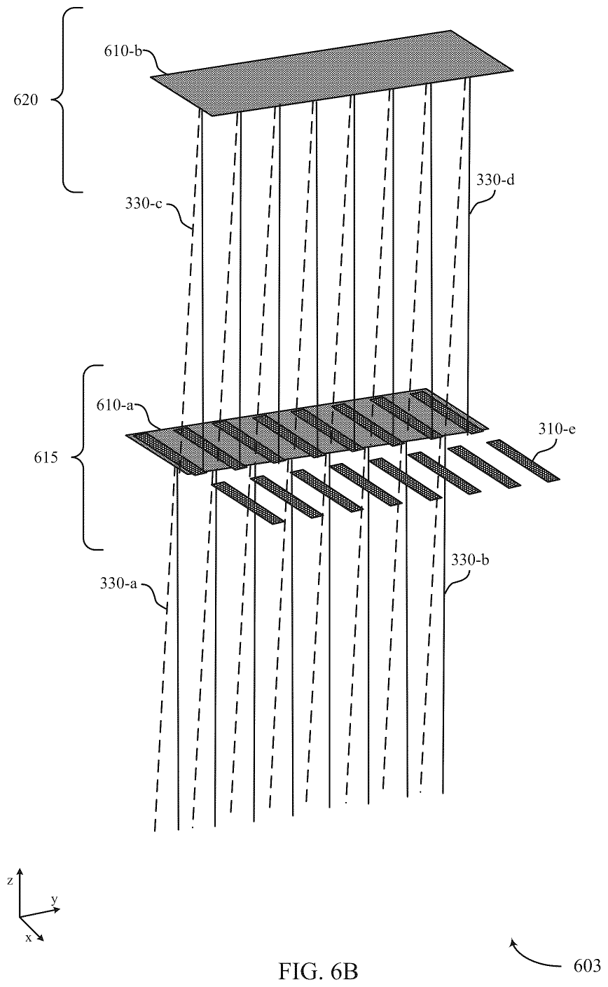

FIG. 6A shows an example of a single-level measurement marker 601 that supports measuring tilt in semiconductor manufacturing in accordance with examples as disclosed herein. Aspects of the single-level measurement marker 601 may be examples of the measurement marker 400. For example, the single-level measurement marker 601 may be a 3D illustration of a portion of the measurement marker 400. For example, as described herein, a set of contacts 310-d (e.g., the set of contacts 310-a or the set of contacts 310-b) may be formed at a level 605 (e.g., first level) of a semiconductor (e.g., a substrate of a wafer, the semiconductor 305, or the semiconductor 501). In response to forming the set of contacts 310-d, a stack of nitride and oxide materials (not shown) may be deposited over the set of contacts 310-d. In response to depositing the stack of nitride and oxide materials 315 of the set of contacts 310-d, a set of cavities 330-a may be etched into the stack of nitride and oxide materials according to the techniques described herein with reference to FIG. 3A.

As described herein, due to the etching procedure, the set of cavities 330-a may be misaligned (e.g., tilted or offset) from a desired set of cavities 330-b. That is, the set of cavities 330-a may be misaligned (e.g., tilted or offset) from the set of contacts 310-d. According to the techniques described herein with reference to FIG. 4, a light 345 may be emitted through the set of cavities 330-a to obtain the measurement of the misalignment 340 at the interface between the set of cavities 330-a and the set of contacts 310-d. In response to measuring the misalignment 340 at the interface between the set of contacts 310-d and the set of cavities 330-a, a shielding material 610-a (e.g., a sea of contacts, where the density of such contacts act as a shield for a next level of the measurement marker 400) may be formed at a level 615 (e.g., second level) of the semiconductor and over the stack of nitride and oxide materials (not shown). Such shielding material 610-a may be used as a shield or mask for a multi-level measurement marker 603, as described herein with reference to FIG. 6B.

FIG. 6B shows an example of a multi-level measurement marker 603 that supports measuring tilt in semiconductor manufacturing in accordance with examples as disclosed herein. Aspects of the multi-level measurement marker 603 may be an example of the measurement marker 400. For example, the multi-level measurement marker 603 may be a 3D illustration of a portion of a multi-level measurement marker 400. The multi-level measurement marker 603 may be formed in response to the formation of the single-level measurement marker 601.

For example, in response to forming the shielding material 610-a, a set of contacts 310-c (e.g., second set of contacts) may be formed at the level 615 (e.g., second level) of the semiconductor (e.g., a substrate of the wafer). Based on forming the set of contacts 310-e, a second stack of nitride and oxide materials (not shown) may be formed over the set of contacts 310-c. Accordingly, a set of cavities 330-c may be etched through the stack of nitride and oxide materials according to the techniques described herein with reference to FIG. 3A.

As described herein, due to the etching procedure, the set of cavities 330-c may be misaligned (e.g., tilted or offset) from a desired set of cavities 330-d. That is, the set of cavities 330-c may be misaligned (e.g., tilted or offset) from the set of contacts 310-c. According to the techniques described herein with reference to FIG. 4, a light 345 may be emitted through the set of cavities 330-c to obtain the measurement of the misalignment 340 at the interface between the set of cavities 330-c and the set of contacts 310-e. In such examples, the shielding material 610-a may prevent the light 345 emitted through the set of cavities 330-c from passing through the set of cavities 330-a, which may reduce the accuracy of the measurement.

In response to measuring the misalignment 340 at the interface between the set of contacts 310-e and the set of cavities 330-c, a shielding material 610-b (e.g., a sea of contacts, where the density of such contacts act as a shield for a next level of the measurement marker 400) may be formed at a level 620 (e.g., third level) of the semiconductor and over the stack of nitride and oxide materials (not shown). Such shielding material 610-b may be used as a shield or mask for additional levels of the multi-level measurement marker 603.

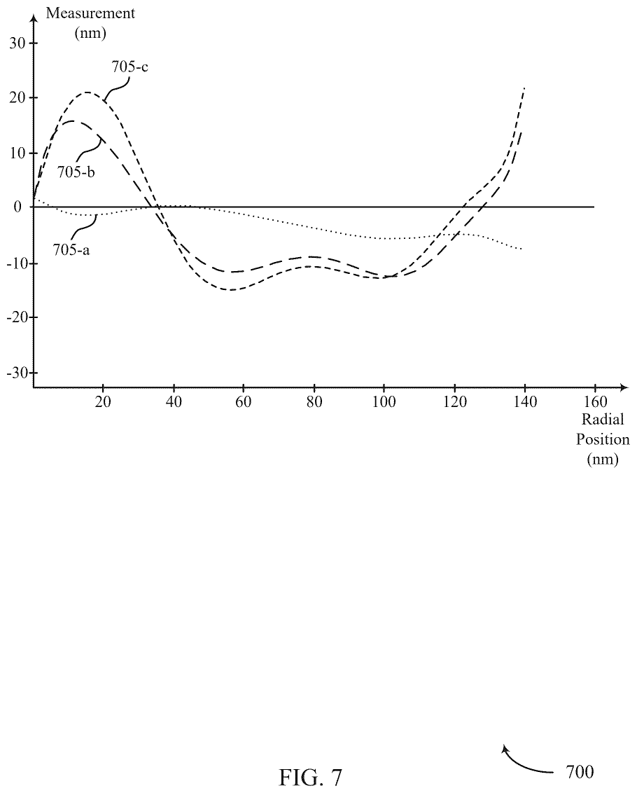

FIG. 7 shows an example of a graph 700 that supports measuring misalignment in semiconductor manufacturing in accordance with examples as disclosed herein. The graph 700 may illustrate a measurement result 705-a, a measurement result 705-b, and a measurement result 705-c (e.g., misalignment measurements, tilt measurements, overlay measurements, offset measurements, among other examples) obtained using various techniques. The X-axis of the graph 700 may correspond to a radial position of the semiconductor shown in nanometers (nm), while the Y-axis of the graph 700 may correspond to the measurements in nm.

The measurement result 705-a may be obtained using a standard measurement marker, where the measurement results 705-a may be less accurate than those of the measurement results 705-b and the measurement results 705-c. The measurement result 705-b may be obtained using the etch back process as described herein, while the measurement result 705-c may be obtained using the measurement marker 400 and according to the techniques described herein. As illustrated, the measurement result 705-b and the measurement result 705-c may be within a threshold quantity of nm, such as five to ten nm, indicating that the measurement results 705-c are indeed accurate.

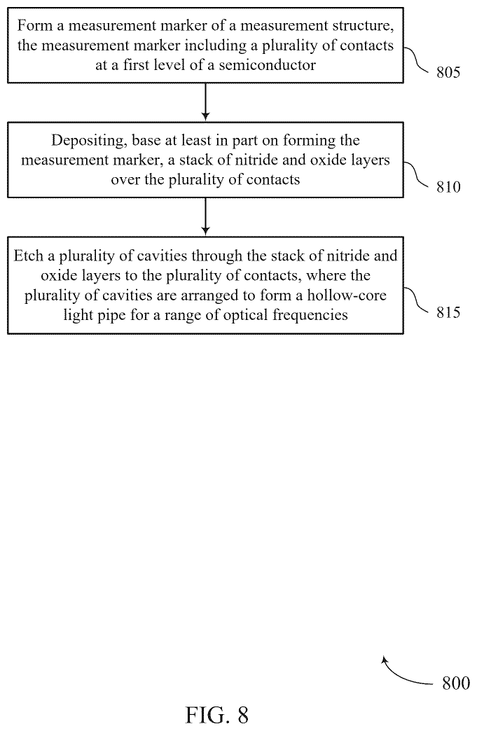

FIG. 8 shows a flowchart illustrating a method 800 that supports measuring tilt in semiconductor manufacturing in accordance with examples as disclosed herein. The operations of method 800 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose.

At 805, the method may include forming a measurement marker of a measurement structure, the measurement marker including a plurality of contacts at a first level of a substrate.

At 810, the method may include forming, based at least in part on forming the measurement marker, a stack of nitride and oxide materials over the plurality of contacts.

At 815, the method may include forming a plurality of cavities through the stack of nitride and oxide materials to the plurality of contacts, where the plurality of cavities are arranged to form a hollow-core light pipe for a range of optical frequencies.

In some examples, an apparatus (e.g., a manufacturing system) as described herein may perform a method or methods, such as the method 800. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for forming a measurement marker of a measurement structure, the measurement marker including a plurality of contacts at a first level of a semiconductor; depositing, based at least in part on forming the measurement marker, a stack of nitride and oxide materials over the plurality of contacts; etching a plurality of cavities through the stack of nitride and oxide materials to the plurality of contacts, where the plurality of cavities are arranged to form a hollow-core light pipe for a range of optical frequencies; and obtaining a measurement at an interface between the plurality of contacts and the plurality of cavities based at least in part on light passing through each of the plurality of cavities.

Aspect 2: The method or apparatus of aspect 1, further including operations, features, circuitry, logic, means, or instructions, or any combination thereof for emitting the light through each of the plurality of cavities based at least in part on etching the plurality of cavities where the measurement is based at least in part on emitting the light through each of the plurality of cavities.

Aspect 3: The method or apparatus of any of aspects 1 through 2, further including operations, features, circuitry, logic, means, or instructions, or any combination thereof for depositing a resistive material over the stack of nitride and oxide materials, the resistive material including a plurality of gaps and each gap of the plurality of gaps being aligned with a respective contact of the plurality of contacts, where etching the plurality of cavities is based at least in part on depositing the resistive material including the plurality of gaps.

Aspect 4: The method or apparatus of any of aspects 1 through 3, further including operations, features, circuitry, logic, means, or instructions, or any combination thereof for obtaining a second measurement between a top of the plurality of cavities and a bottom of the plurality of cavities based at least in part on the light passing through the plurality of cavities.

Aspect 5: The method or apparatus of any of aspects 1 through 4, further including operations, features, circuitry, logic, means, or instructions, or any combination thereof for selecting a wavelength of the light that is passed through each of the plurality of cavities, where an accuracy of the measurement is based at least in part on the wavelength.

Aspect 6: The method or apparatus of aspect 5, where the wavelength is selected based at least in part on a pitch of the plurality of cavities, a diameter of the plurality of cavities, a height of the plurality of cavities, a size of the plurality of contacts, or a combination thereof.

Aspect 7: The method or apparatus of any of aspects 1 through 6, further including operations, features, circuitry, logic, means, or instructions, or any combination thereof for selecting a density of the plurality of contacts, where forming the measurement marker is based at least in part on selecting the density of the plurality of contacts, and where an accuracy of the measurement is based at least in part on the density of the plurality of contacts.

Aspect 8: The method or apparatus of any of aspects 1 through 7, further including operations, features, circuitry, logic, means, or instructions, or any combination thereof for forming, on the measurement marker, a second plurality of contacts adjacent to the plurality of contacts, the second plurality of contacts being reference contacts, where the measurement is further based at least in part on comparing the second plurality of contacts with the plurality of contacts.

Aspect 9: The method or apparatus of aspect 8, where the second plurality of contacts are on an outer area of the measurement marker and the plurality of contacts are on an inner area of the measurement marker.

Aspect 10: The method or apparatus of any of aspects 8 through 9, where the second plurality of contacts are on an inner area of the measurement marker and the plurality of contacts are on outer area of the measurement marker.

Aspect 11: The method or apparatus of any of aspects 1 through 10, further including operations, features, circuitry, logic, means, or instructions, or any combination thereof for forming a wafer including a second plurality of contacts at the first level of the semiconductor, where the measurement structure is formed on the wafer.

Aspect 12: The method or apparatus of aspect 11, where the second plurality of contacts at the first level of the semiconductor are associated with a memory array; the plurality of contacts on the measurement marker are used for one or more measurements; and the second plurality of contacts at the first level of the semiconductor are used for one or more electrical connections.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 13: A memory device, including: a substrate; a measurement structure formed on the substrate and including: a measurement marker including a plurality of contacts at a first level of the substrate; a stack of nitride and oxide materials positioned over the plurality of contacts; and a plurality of cavities etched through the stack of nitride and oxide materials to the plurality of contacts, where the plurality of cavities are arranged to form a hollow-core light pipe for a range of optical frequencies.

Aspect 14: The memory device of aspect 13, where the measurement marker includes a second plurality of contacts at the first level of the substrate.

Aspect 15: The memory device of aspect 14, where a first subset of the plurality of contacts and a first subset of the second plurality of contacts are formed in a first direction, and a second subset of plurality of contacts and a second subset of the second plurality of contacts are formed in a second direction.

Aspect 16: The memory device of any of aspects 14 through 15, where the plurality of contacts are positioned on an outer area of the measurement marker and the second plurality of contacts are positioned on an inner area of the measurement marker.

Aspect 17: The memory device of any of aspects 14 through 16, where the plurality of contacts are positioned on an inner area of the measurement marker and the second plurality of contacts are positioned on an outer area of the measurement marker.

Aspect 18: The memory device of any of aspects 13 through 17, where a density of the plurality of contacts on the measurement marker is based at least in part on a density of a second plurality of contacts at the first level of the substrate, and the hollow-core light pipe formed by the plurality of cavities is based at least in part on the density of the plurality of contacts on the measurement marker.

Aspect 19: The memory device of aspect 18, where the second plurality of contacts at the first level of the substrate are associated with a memory array and are used for one or more electrical connections, and the plurality of contacts on the measurement marker are used for one or more measurements.

Aspect 20: The memory device of any of aspects 13 through 19, further including: a second measurement marker of the measurement structure, the second measurement marker positioned over the measurement marker and including a second plurality of contacts at a second level of the substrate, the second level of the substrate being positioned over the first level of the substrate; a second stack of nitride and oxide materials positioned over the second plurality of contacts; and a second plurality of cavities etched through the second stack of nitride and oxide materials to the second plurality of contacts, where the second plurality of cavities are arranged to form a second hollow-core light pipe over the range of optical frequencies.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “material” or “level” used herein refers to a stratum or sheet of a geometrical structure (e.g., relative to a substrate). Each material or level may have three dimensions (e.g., height, width, and depth) and may cover at least a portion of a surface. For example, a material or level may be a three dimensional structure where two dimensions are greater than a third, e.g., a thin-film. Materials or levels may include different elements, components, or materials, or combinations thereof. In some examples, one material or level may be composed of two or more submaterials or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial materials of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device, comprising:
a substrate; and
a measurement structure formed on the substrate and including:
a measurement marker comprising a plurality of contacts at a first level of the substrate;
a stack of nitride and oxide materials positioned over the plurality of contacts; and
a plurality of cavities etched through the stack of nitride and oxide materials to the plurality of contacts, wherein the plurality of cavities are arranged to form a hollow-core light pipe for a range of optical frequencies.

2. The memory device of claim 1, wherein the measurement marker comprises a second plurality of contacts at the first level of the substrate.

3. The memory device of claim 2, wherein a first subset of the plurality of contacts and a first subset of the second plurality of contacts are formed in a first direction, and a second subset of plurality of contacts and a second subset of the second plurality of contacts are formed in a second direction.

4. The memory device of claim 2, wherein the plurality of contacts are positioned on an outer area of the measurement marker and the second plurality of contacts are positioned on an inner area of the measurement marker.

5. The memory device of claim 2, wherein the plurality of contacts are positioned on an inner area of the measurement marker and the second plurality of contacts are positioned on an outer area of the measurement marker.

6. The memory device of claim 1, wherein a density of the plurality of contacts on the measurement marker is based at least in part on a density of a second plurality of contacts at the first level of the substrate, and the hollow-core light pipe formed by the plurality of cavities is based at least in part on the density of the plurality of contacts on the measurement marker.

7. The memory device of claim 6, wherein:
the second plurality of contacts at the first level of the substrate are associated with a memory array and are used for one or more electrical connections, and
the plurality of contacts on the measurement marker are used for one or more measurements.

8. The memory device of claim 1, further comprising:
a second measurement marker of the measurement structure, the second measurement marker positioned over the measurement marker and comprising a second plurality of contacts at a second level of the substrate, the second level of the substrate being positioned over the first level of the substrate;
a second stack of nitride and oxide materials positioned over the second plurality of contacts; and
a second plurality of cavities etched through the second stack of nitride and oxide materials to the second plurality of contacts, wherein the second plurality of cavities are arranged to form a second hollow-core light pipe over the range of optical frequencies.

9. A method of manufacturing, comprising:
forming a measurement marker of a measurement structure, the measurement marker comprising a plurality of contacts at a first level of a substrate;
forming, based at least in part on forming the measurement marker, a stack of nitride and oxide materials over the plurality of contacts; and
forming a plurality of cavities through the stack of nitride and oxide materials to the plurality of contacts, wherein the plurality of cavities are arranged to form a hollow-core light pipe for a range of optical frequencies.

10. The method of claim 9, further comprising:
obtaining a measurement at an interface between the plurality of contacts and the plurality of cavities based at least in part on light passing through each of the plurality of cavities.

11. The method of claim 10, further comprising:
emitting the light through each of the plurality of cavities based at least in part on etching the plurality of cavities wherein the measurement is based at least in part on emitting the light through each of the plurality of cavities.

12. The method of claim 10, further comprising:
obtaining a second measurement between a top of the plurality of cavities and a bottom of the plurality of cavities based at least in part on the light passing through the plurality of cavities.

13. The method of claim 10, further comprising:
selecting a wavelength of the light that is passed through each of the plurality of cavities, wherein an accuracy of the measurement is based at least in part on the wavelength.

14. The method of claim 13, wherein the wavelength is selected based at least in part on a pitch of the plurality of cavities, a diameter of the plurality of cavities, a height of the plurality of cavities, a size of the plurality of contacts, or a combination thereof.

15. The method of claim 10, further comprising:
selecting a density of the plurality of contacts, wherein forming the measurement marker is based at least in part on selecting the density of the plurality of contacts, and wherein an accuracy of the measurement is based at least in part on the density of the plurality of contacts.

16. The method of claim 10, further comprising:
forming, on the measurement marker, a second plurality of contacts adjacent to the plurality of contacts, the second plurality of contacts being reference contacts, wherein the measurement is further based at least in part on comparing the second plurality of contacts with the plurality of contacts.

17. The method of claim 16, wherein the second plurality of contacts are on an outer area of the measurement marker and the plurality of contacts are on an inner area of the measurement marker.

18. The method of claim 16, wherein the second plurality of contacts are on an inner area of the measurement marker and the plurality of contacts are on outer area of the measurement marker.

19. The method of claim 9, further comprising:
depositing a resistive material over the stack of nitride and oxide materials, the resistive material comprising a plurality of gaps and each gap of the plurality of gaps being aligned with a respective contact of the plurality of contacts, wherein forming the plurality of cavities is based at least in part on depositing the resistive material comprising the plurality of gaps.

20. The method of claim 9, further comprising:
forming a wafer comprising a second plurality of contacts at the first level of the substrate, wherein the measurement structure is formed on the wafer.

21. The method of claim 20, wherein:
the second plurality of contacts at the first level of the substrate are associated with a memory array,
the plurality of contacts on the measurement marker are used for one or more measurements, and
the second plurality of contacts at the first level of the substrate are used for one or more electrical connections.

22. The method of claim 9, further comprising:
forming, over the measurement marker, a second measurement marker of the measurement structure, the second measurement marker comprising a second plurality of contacts at a second level of the substrate;
forming, based at least in part on forming the second measurement marker, a second stack of nitride and oxide materials over the second plurality of contacts; and
forming a second plurality of cavities through the second stack of nitride and oxide materials to the second plurality of contacts, wherein the second plurality of cavities are arranged to form a second hollow-core light pipe for the range of optical frequencies.

23. A product formed by a process, comprising:
forming a measurement marker of a measurement structure, the measurement marker comprising a plurality of contacts at a first level of a substrate;
forming, based at least in part on forming the measurement marker, a stack of nitride and oxide materials over the plurality of contacts; and
forming a plurality of cavities through the stack of nitride and oxide materials to the plurality of contacts, wherein the plurality of cavities are arranged to form a hollow-core light pipe for a range of optical frequencies.
